(19) United States
(12) Patent Application Publication
(10) Pub. No.: US 2006/0139086 A1
(43) Pub. Date: Jun. 29, 2006

(54) Circuit arrangement for bridging high voltages using a switching signal

(75) Inventors: Steffen Heinz, Burgstadt (DE); Gunter Ebest, Chemnitz (DE); Jurgen Dietrich, Mullrose (DE); Jurgen Knopke, Brieskow-Finkenheard (DE); Wolfgang Miesch, Frankfurt (DE)

Correspondence Address: ROBERT W. BECKER & ASSOCIATES, 707 HIGHWAY 66 EAST, SUITE B, TIJERAS, NM, 87059, US

(73) Assignee: ALPHA MICROELETRONICS GMBH

(21) Appl. No.: 10/528,925

(22) PCT Filed: Sep. 25, 2003
(86) PCT No.: PCT/DE03/03264

§ 371 Date: Sep. 23, 2005

(30) Foreign Application Priority Data
Sep. 27, 2002 (DE) 102 46 083.3

(51) Int. Cl. H03L 5/00

(52) U.S. Cl. 327/333

(57) ABSTRACT

A circuit arrangement for bridging high voltages using a switching signal as a dynamic voltage level shifter includes switching signal sequences that can be processed or provided at different voltage levels. Thus, any technology for integrated high-voltage circuit involving any isolation method can be used to produce the circuit arrangements. The circuit arrangements make available signal levels with conventional voltage levels of between 3 V and 15 V at another voltage level, using a potential differential of a few volts up to several hundred volts, depending on the technology and application used. The potential differential between the input voltage level, or voltage transmitter and the output voltage level, or voltage receiver, can be either positive or negative, or can vary in intensity.

The invention relates to a circuit arrangement for bridging high voltages using a switching signal as a dynamic voltage level shifter.

DE 195 02 116 C2 (MOS circuit arrangement for switching high voltages on a semi-conductor chip) is a realization of an integrated circuit on a semi-conductor chip for switching higher voltages. A further circuit for switching high voltages is disclosed by WO 00/70763.

Further circuits are disclosed by DECLERCQ, M., et al, 5 V-to-75 V CMOS Output Interface Circuits, in: 1993 IEEE International Solid-State Circuits Conference, page 162-163; and BALLAN, H., et al: High voltage devices and circuits in standard CMOS technology, Kluwer Academic Publishers, 1999, page 182 and following. There, a concept for a static level-shifter is provided, which comprises a source-coupled differential amplifier with positive back coupling. By means of the positive back coupling, the amplifier is coupled and works as a “flip-flop”. The digital signal sequence is conducted inverted and non-inverted to transistors, which work over the entire voltage range of the voltage level shifter, which means that these must be voltage-fixed. The circuit forms a co-called voltage mirror. Consequently, a voltage, which should have the size of the logic level, is mirrored on the upper voltage rail as a high voltage supply voltage. The maximum voltage differential between the voltage mass and the high voltage supply voltage is determined only by the voltage strength of both transistors.

JP 2001-223 575 A discloses a voltage level shifter with a voltage transmitter with terminals (VDD, VSS) for a low voltage and a voltage receiver with terminals (HVDD, HVSS) for a voltage that is high relative to the low voltage. The voltage receiver comprises a first and second inverter circuit. The outlet of an inverter circuit of the voltage transmitter is connected with a capacitor (C1) as the high voltage capacitor with the inlet of an inverter circuit of the voltage receiver.

These circuits have the disadvantage that a continuous current flows between the high voltage supply voltage and the circuit mass, which is an essential component of the power loss. This increases linearly with the voltage differential to be overcome. The current level cannot be selected to be as low as desired, since the transistor capacities, primarily the high voltage transistors, and parasitic circuit capacities (transit path capacities, isolation capacities) must be recharged. This affects the power loss as well as the speed (barrier frequency) of the circuit. This circuit variation is not suitable for multi-circuit applications and circuits with high voltages. The second disadvantage lies in space requirements of the circuits. The high voltage transistors require a large chip surface, according to the voltage strength. With multi-circuit systems, these surfaces add up to a considerable part of the total chip surface.

The invention provided in claim 1 is based on the problem of producing a high voltage circuit which processes or makes available switching signal sequences at different voltage levels.

This problem is solved with the features set forth in claim 1.

The circuit arrangement for bridging high voltages with a switching signal as a dynamic voltage level shifter is characterized especially in that switching signal sequences can be processed or made available at different voltage levels. An essential advantage is that any technology for integrated high voltage circuits can be applied with any isolation method for realizing the circuit arrangement for commutating high voltages according to the present invention.

The circuit arrangements for switching over high voltages, also designated as dynamic voltage level shifters, make available digital signal levels with conventional voltage levels between approximately 3 V to 15 V at another voltage level, using a potential differential of a few volts up to several hundred volts (depending on the technology and application used). Thus, the potential differential between the input voltage level, or voltage transmitter, and the output voltage level, or voltage receiver can be either positive or negative, or can vary in intensity.

The circuit arrangement for bridging high voltages with a switching signal comprises inverter circuits. Those of the voltage transmitter are connected with the terminals Vdd and Vss for a low voltage and those of the voltage receiver are connected with terminals Vddh1 and Vddh2 for a voltage that is high relative to the circuit mass Vss. The connections of the voltage transmitter and the voltage receiver take place via capacitors C1 and C2 as high voltage capacitors, so that between the voltage levels, a continuous current flow is provided in the form of the voltage transmitter and the voltage receiver. The signal transmission takes place with the assistance of a low charge amount ΔQ, which is alternatingly charged and discharged. Thus, a differential operation is provided, so that also advantageously, a high signal-to-noise ratio relative to parasitic signal couplings is achieved, based on the differential principle; C1 is charged to a charge ΔQ and C2 simultaneously discharges to a charge ΔQ and vice versa. The required voltage-fixed components of the circuit arrangement of the present invention are limited to two high voltage capacitors. These can be layered, so that smaller space requirements with higher capacities per surface are required.

The inverter circuits of the voltage receiver are cross-linked, so that in the voltage receiver, no protective diodes are necessary for protecting subsequent components from voltage spikes. A further advantage of this cross-linking is that no small high-voltage capacitors C1 and C2 are required. Only the parasitic capacities of the cross-linked inverter circuits must be overcome. Their capacities can be very small, so that also reduced chip surfaces are necessary to realize these capacities.

The circuit arrangements for bridging high voltages with a switching signal according to the present invention advantageously are direction-independent, so that both a positive or negative voltage differential between the voltage transmitter and the voltage receiver can be overcome.

Thus, the circuit arrangements of the present invention for bridging high voltages with a switching signal are suitable for high voltage circuits, which process or make available switching signal sequences at different voltage levels. Applications are, for example, motor-driven circuits, audio amplifiers according to the class D principle or control circuits for electrostatic actors. Electrostatic actors include piezo-ceramic structures or movable mirror arrays.

Advantageous embodiments of the invention are provided in claims 2 through 9.

According to an embodiment of claim 3, a third inverter circuit between the terminals Vdd and Vss allows the signal to be inverted twice from a low signal at the inlet IN, so that this is conducted in-phase to the input signal to the capacitor C1. The outlet of the third inverter circuit is connected with the inlet of the first inverter circuit of the voltage transmitter and its inlet is connected with the inlet of the second inverter circuit of the voltage transmitter as well as with the terminal IN as the inlet of the circuit arrangement for bridging high voltage with a switching signal. The signal moves inverted via the second inverter circuit of the voltage transmitter to the capacitor C2. Thus, a differential operation is provided.

A fourth and fifth inverter circuit between the terminals Vddh1 and Vddh2 are outlet inverters as provided in claim 3, whereby the inlet of the fourth inverter circuit is connected with the inlet of the first inverter circuit of the voltage receiver, the inlet of the fifth inverter circuit is connected with the inlet of the second inverter circuit of the voltage receiver, the outlet of the fourth inverter circuit is connected with the terminal OUT1 as the first outlet of the voltage receiver and the outlet of the fifth inverter circuit is connected with the terminal OUT2 as the second outlet of the voltage receiver, according to the embodiment of claim 3. Beginning as a low signal at the inlet of the voltage transmitter, on the outlet OUT1, a low signal with reference to the high-voltage voltage supply exists and on the outlet OUT2, a high signal with reference to the high-voltage voltage supply exists.

A sixth and a seventh inverter circuit between the terminals Vdd and Vss according to the embodiment of claim 4 are driver stages, whereby the inlet of the seventh inverter circuit is connected with the inlet of the third inverter circuit and with the terminal IN as the inlet of the circuit arrangement for bridging high voltages with a switching signal, the outlet of the seventh inverter circuit is connected with the inlet of the sixth inverter circuit and the outlet of the sixth inverter circuit is connected with the inlet of the second inverter circuit of the voltage transmitter. In this manner, the signal, originating from a low-signal, moves inverted to the inlet IN onto the capacitor C2.

The embodiment of claim 5, in which the inverter circuit comprises two complementary transistors connected in series, leads to inverter circuits with almost ideal performance. Both transistors are alternately the active element and the load element. In a resting state, the power consumption with use of MOSFETs is very minimal. These are only due to leakage currents. Power consumption occurs only during switching over and, therefore, proportionally to working frequency. This exists by the recharging of the load capacities and, in small part, by a cross flow.

The capacities for signal transmission between the voltage transmitter and the voltage receiver are charged to the voltage differential to be overcome, according to the embodiment of claim 6. For signal transmission, its value varies only to ΔQ, whereby the power consumption is independent from the voltage differential to be overcome.

The circuit arrangement for bridging high voltages with a switching signal can be realized as integrated semi-conductor circuits made with semi-conductor processes, on the one hand, with CMOS circuits as the inverter circuits and, on the other hand, as a stack of layers with circuit stopper implantation, field oxide, poly-silicon, CVD-oxide, metal, CVD-oxide, metal, and so on, whereby the layers are electrically alternatingly connected, according to claim 7. This fulfills advantageously the requirements for minimal power consumption and minimal space requirements.

The embodiment of claim 8, whereby the voltage transmitter, the capacitors, and the voltage receiver, respectively, are surrounded by trenches for voltage isolation, represents a favorable realization.

An essential advantage of the circuit arrangement for bridging high voltages with a switching signal, as provided in claim 9, is that the semi-conductor processes for integrated high voltage circuits can be applied with any isolation for the voltage transmitter, the high voltage capacitors, and the voltage receiver. Therefore, the multifaceted variations for realizing the present invention are provided according to economic requirements, method technology manufacturing requirements, and/or supplied application specifications.

One embodiment of the present invention is shown in the drawings and will be described next in greater detail.

### IN THE DRAWINGS

FIG. 1 shows a block diagram of the base circuit of a circuit arrangement for switching over high voltages;

FIG. 2 shows a realization of the base circuit of a circuit arrangement for switching over high voltages;

FIG. 3 shows a circuit arrangement for switching over high voltages;

FIG. 4 shows a circuit arrangement for switching over high voltages; and

FIG. 5 shows a principle representation of regions of a circuit arrangement for switching over high voltages on a semi-conductor chip.

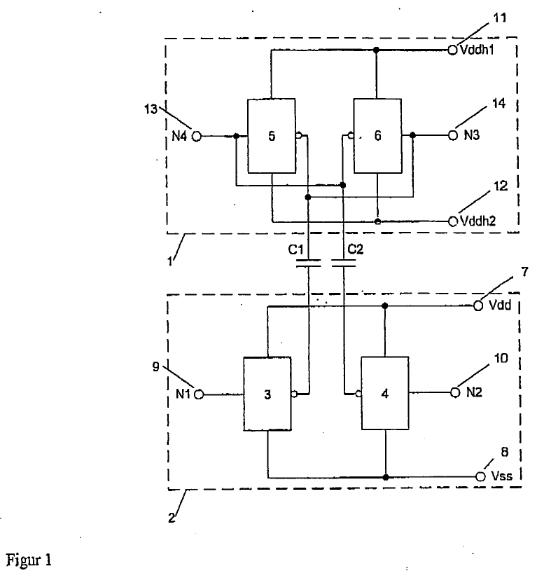

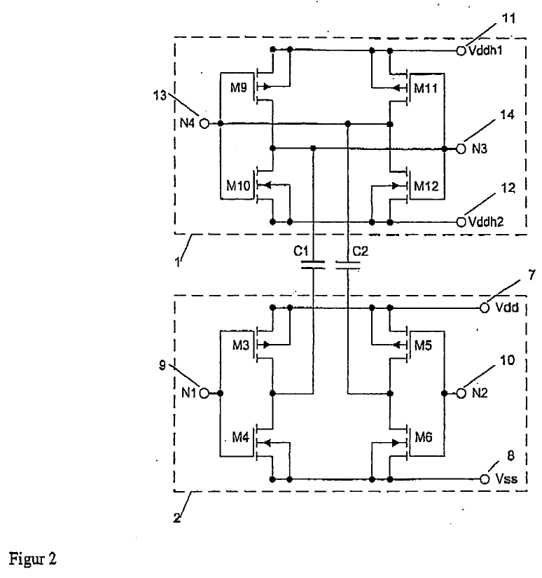

A circuit arrangement for bridging high voltages with a switching signal as a dynamic voltage level shifter comprises a voltage transmitter 2 with terminals Vdd 7, Vss 8 for a low voltage and a voltage receiver 1 with terminals Vddh1 11 Vddh2 12 for a high voltage relative to the low voltage between the terminals Vdd 7 and Vss8, comprising respectively a first inverter circuit and a second inverter circuit. FIG. 1 shows a block diagram of the base circuit of a circuit arrangement for bridging high voltages with a switching signal and FIG. 2 shows a realization of this base circuit.

The inverter circuits of the voltage transmitter 2 are connected between the terminals Vdd 7 and Vss 8, whereby the Vss 8 is the voltage mass and the inverter circuits of the voltage receiver 1 are connected between the terminals Vddh1 11 and Vddh2 12. The outlet of the first inverter circuit 3 of the voltage transmitter 2 is connected via a first capacitor C1 as a high voltage capacitor with the inlet of the second inverter circuit 6 of the voltage receiver 1 and with the outlet of the first inverter circuit 5 of the voltage receiver 1. The outlet of the second inverter circuit 4 of the voltage transmitter 2 is connected via a second capacitor C2 as a high voltage capacitor with the inlet of the first inverter circuit 5 of the voltage receiver 1 and the outlet of the second inverter circuit 6 of the voltage receiver 1 (shown in FIG. 1). The inlets of the first inverter circuit 3 and the second inverter circuit 4, respectively, of the voltage transmitter 2 represent a non-inverted and an inverted inlet. The outlets of the first inverter circuit 5 and the second inverter circuit 6 of the voltage receiver 1 are outlet nodes.

The inverter circuits 3, 4, 5, 6 each comprise two complementary transistors connected in series (shown in FIG. 2). Thus, the following associations are provided:

a first inverter circuit 3 of the voltage transmitter 2: transistors M3, M4;

second inverter circuit 4 of the voltage transmitter 2: transistors M5, M6;

first inverter circuit 5 of the voltage receiver: transistors M9, M10; and

second inverter circuit 6 of the voltage receiver 1: transistors M11, M12.

All transistors are MOSFETs (MOSFET is an abbreviation for a “metal oxide silicon field effect transistor”).

With such a realization, a continuous current flow does not exist between the voltage transmitter 2 and the voltage receiver 1 and, therewith, between the voltage level Vdd−Vss and the voltage level Vddh1−Vddh2. The signal transmission takes place with the help of a small charge value ΔQ, which alternatingly charges and discharges. Based on the cross-linked arrangement of the first inverter circuit 5 of the voltage receiver 1 and the second inverter circuit 6 of the voltage receiver 1, no protective diodes are required, so that small capacitors C1, C2, respectively, can be used as high voltage capacitors. At the same time, both a positive and negative voltage differential between the voltage transmitter 2 and the voltage receiver 1 can be overcome. The voltage differential to be overcome by the circuit arrangement of the present invention lies between the supply voltages, on the one hand, Vdd−Vss, and on the other hand, Vddh1−Vddh2, whereby these have both a positive and negative sign and simultaneously can vary in value. The maximum value of the voltage differential to be overcome depends exclusively on the voltage strength of both capacitors C1, C2. The function is that both capacitors C1, C2 are charged to the voltage differential to be overcome and their charging subsequently varies at a small value for signal transmission:

ΔQ=C×(Vdd−Vss)/1/

The voltage differential (Vdd−Vss) corresponds with the low voltage supply voltage between the terminals 7 and 8. The recharging impulse with a low-high flank at the inlet N1 9 is transmitted via the first inverter circuit 3 of the voltage transmitter 2, comprising transistors M3 and M4, to the capacitor C1. The inverted signal (high-low flank) at the nodes N2 10 is simultaneously transmitted via the second inverter circuit 4 of the voltage transmitter 2, comprising transistors M5 and M6, to the capacitor C2. The capacitor C1 is charged on the transmitter side to the value of equation /1/ and the capacitor C2 discharged (differential principle). This charging is relayed via the voltage differential to be overcome to the voltage receiver 1.

By means of the described manner of operation, the current consumption can be reduced greatly and the power consumption of the circuit arrangement of the present invention is practically independent from the voltage differential to be overcome. At the same time, the applied differential principle (C1 is charged to ΔQ, C2 is discharged to ΔQ and vice versa) guarantees a high signal-to-noise ratio relative to push-push signals.

In addition, very small capacity values are suited for the capacitors C1, C2, since exclusively the parasitic capacities of the cross-linked inverter circuits 5, 6 must be overcome. At the same time, these assume the protective function of overvoltage and undervoltage of the additional circuit. Protective diodes can be eliminated.

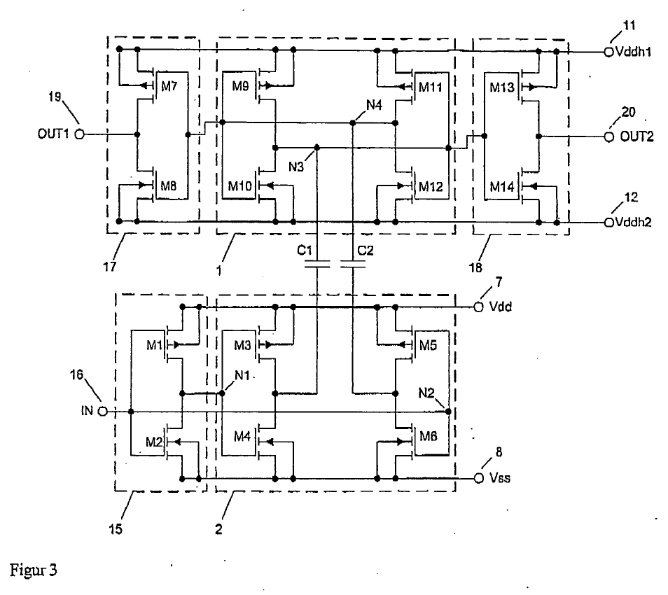

With a first embodiment of the exemplary example, a third inverter circuit 15 is connected between terminals Vdd 7 and Vss 8, in such a way that the outlet of the third inverter circuit 15 is connected with the inlet of the first inverter circuit 3 of the voltage transmitter 2 and the inlet of the third inverter circuit 15 is connected with the inlet of the second inverter circuit 4 of the voltage transmitter 2 and the terminal IN 16 as the inlet of the circuit arrangement for bridging high voltages with a switching signal as a dynamic voltage level shifter. In addition, a fourth inverter circuit 17 and a fifth inverter circuit 18 are connected between the terminals Vddh1 11 and Vddh2 12. In this connection, the inlet of the fourth inverter circuit 17 is connected with the inlet of the first inverter circuit 5 of the voltage receiver 1, the inlet of the fifth inverter circuit 18 is connected with the inlet of the second inverter circuit 6 of the voltage receiver 1, the outlet of the fourth inverter circuit 17 is connected with the terminal OUT 1 19 as the first outlet of the voltage receiver 1 and the outlet of the fifth inverter circuit 18 is connected with the terminal OUT 2 20 as the second outlet of the voltage receiver 1. The third inverter circuit 15 is an inlet inverter for the voltage transmitter 2 and the fourth inverter circuit 17 and the fifth inverter circuit 18 are outlet inverters of the voltage receiver 1. FIG. 3 shows this type of circuit arrangement realized for bridging high voltage with a switching signal.

The supply voltages of the voltage transmitter 2 between the terminals Vdd 7 and Vss 8 and the voltage receiver between Vddh1 11 and Vddh2 12 each are 12 V, for example. The voltage differential between the voltage transmitter 2 and the voltage receiver 1 to be overcome, that is, between terminal Vss 8 and terminal Vddh1 11, amounts to 200 V for example. Thus, a voltage drop of approximately 188 V results for the capacitors C1, C2.

Beginning from a low signal (approximately 0 V) at the inlet IN 16, the signal is conducted inverted twice (that is, in-phase to the inlet signal) by the third inverter circuit 15, comprising transistors M1 and M2, and the first inverter circuit 3 of the voltage transmitter 2, comprising transistors M3 and M4, to capacitor C1. The signal moves inverted to the capacitor C2 via the second inverter circuit 4 of the voltage transmitter 2, comprising transistors M5 and M6.

Therefore, for the capacitor C1, a voltage drop of 188 V between the voltage potentials 0 V and 188 V is provided, and for the capacitor C2, a voltage drop of 188 V between the voltage potentials 12 V and 200 V, respectively, is provided with reference to the voltage mass at terminal Vss 8. A voltage potential of approximately 188 V exists at the outlet node N3 14 of the voltage receiver 1 and at the outlet node N4 13, a voltage potential of 200 V exists. Via the fourth inverter circuit 17, comprising transistors M7 and M8, a low signal exists at the outlet OUT 1 19 with reference to the voltage between Vddh1 11 and Vddh2 12, that is, a potential relative to the terminal Vss 8 of 188 V. At the outlet OUT2 20, a high signal with reference to the voltage between Vddh1 11 and Vddh2 12 is provided via the fifth inverter circuit 18, comprising transistors M13 and M14, that is, a potential relative to the terminal Vss 8 of approximately 200 V. At the outlet OUT1 19, as a result, the signal displaced to the voltage differential to be overcome is again available. At the outlet OUT2 20, the inverted signal can be engaged.

If the low signal alternating at the inlet IN 16 of the voltage transmitter 2 changes to a high signal, the charge of the capacitor C1 increases to the value ΔQ and the charge on the capacitor C2 is reduced to the value ΔQ (equation /1/). This change in charge is relayed to the voltage receiver 1 and leads to a pushing-over of the cross-linked inverter circuit into the second stable state. In this manner, the fourth inverter circuit 17 changes its output signal at the outlet OUT1 19 to a high signal relative to the voltage between Vddh1 11 and Vddh2 12 and the fifth inverter circuit 18 changes its output signal at outlet OUT2 20 to a low signal relative to the voltage between Vddh1 11 and Vddh2 12.

With a second embodiment, as a modification of the first embodiment, a sixth inverter circuit 21 and a seventh inverter circuit 22 are connected between the terminals Vdd 7 and Vss 8. Therefore, the inlet of the seventh inverter circuit 22 is connected with the inlet of the third inverter circuit 15 and with the terminal IN 16 as the inlet of the circuit arrangement for bridging high voltages with a switching signal, and the outlet of the seventh inverter circuit 22 is connected with the inlet of the sixth inverter circuit 21 and the outlet of the sixth inverter circuit 21 is connected with the inlet of the second inverter circuit 4 of the voltage transmitter 2.

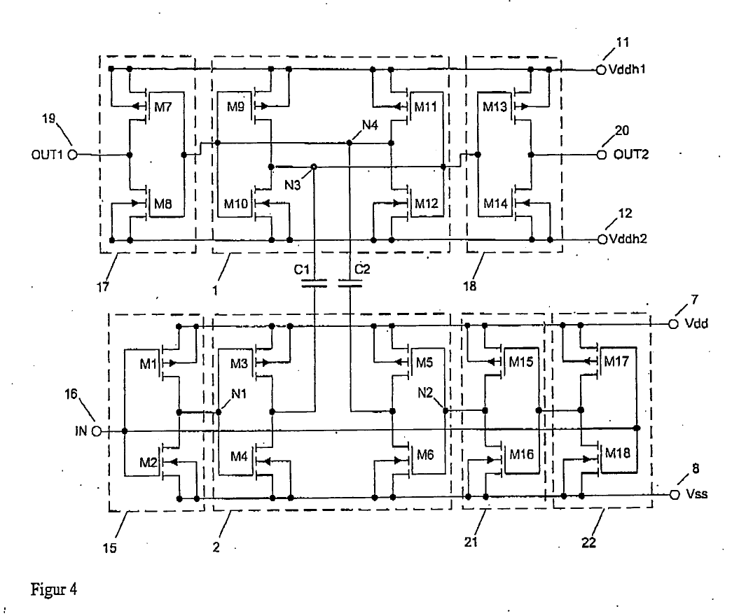

The sixth inverter circuit 21, comprising transistors M15 and M16, and the seventh inverter circuit 22, comprising transistors M17 and M18, are driver stages (shown in FIG. 4).

As a modification of the first embodiment, the signal beginning from a low signal (approximately 0 V) at the inlet IN 16 of the circuit arrangement moves to the capacitor C2 via the seventh inverter circuit 22, the sixth inverter circuit 21 and the second inverter circuit 4 of the voltage transmitter 2. The further function corresponds with the first embodiment. The distribution of multiple inverter circuits connected behind one another, in this embodiment, the seventh inverter circuit 22 and the sixth inverter circuit 21, leads to higher driver powers and, therewith, steeper circuit flanks.

The circuit arrangements for bridging high voltages with a switching signal as a dynamic voltage level shifter can be realized as a semi-conductor circuit made with semi-conductor processes, on the one hand, with CMOS circuits (CMOS is an abbreviation for “complementary metal oxide semiconductor”) as the inverter circuits and on the other hand, stacked layers with channel stopper-implantation, field oxide, poly-silicon, CVD-oxide (CVD is an abbreviation for “chemical vapor deposition”), metal, CVD-oxide, metal, and so on, whereby the layers are alternatingly connected electrically, as the first capacitor C1 and as the second capacitor C2. The individual components of the circuit arrangement for bridging high voltages with a switching signal are regions of a semi-conductor chip as follows:

two regions 23a, 23b are the voltage transmitter 2;

one region 24 is the first capacitor C1;

one region 25 is the second capacitor C2; and

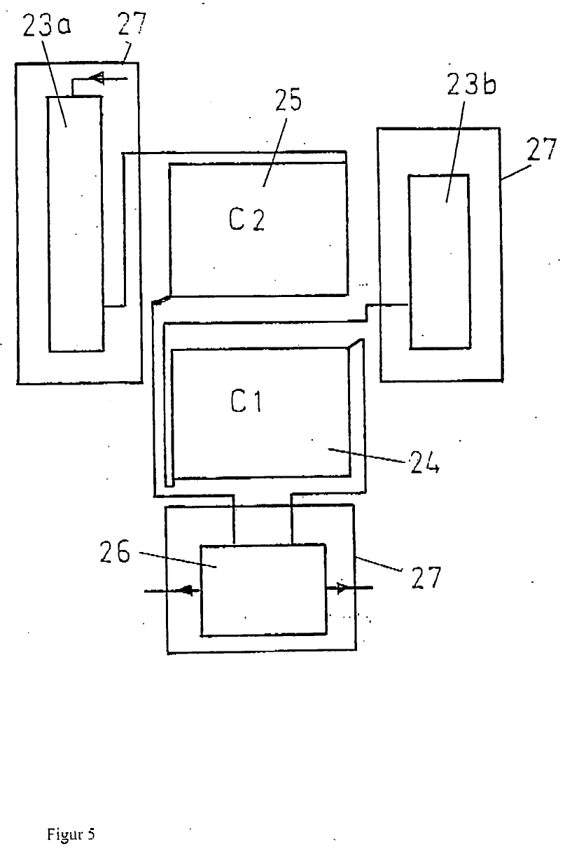

one region 26 is the voltage receiver 1, whereby the regions each are surrounded by trenches 27 for voltage isolation (shown in FIG. 5). The surface requirements for a capacitor C1, C2 of approximately 0.8 pF amounts to 10,000 μm², for example.

The circuit arrangements for bridging high voltages with a switching signal can be embodied as single-circuit or multi-circuits on a semi-conductor chip.

1-9. (canceled)

10. A circuit arrangement for bridging high voltages using a switching signal, comprising:
a voltage transmitter with first and second terminals fbr a low voltage;
a voltage receiver with third and fourth terminals for a higher voltage relative to the low voltage between the first and second terminals, wherein the voltage transmitter and the voltage receiver each comprise a first inverter circuit and a second inverter circuit,
wherein the inverter circuits of the voltage transmitter are connected between the first and second terminals and the inverter circuits of the voltage receiver are connected between the third and fourth terminals,
wherein an outlet of the first inverter circuit of the voltage transmitter is connected via a first capacitor as a high voltage capacitor with an inlet of the second inverter circuit of the voltage receiver and an outlet of the first inverter circuit of the voltage receiver, and an outlet of the second inverter circuit of the voltage transmitter is connected via a second capacitor as a high voltage capacitor with an inlet of the first inverter circuit of the voltage receiver and an outlet of the second inverter circuit of the voltage receiver,
wherein the inlets of the first inverter circuit and the second inverter circuit, respectively, of the voltage transmitter are a non-inverted and an inverted inlet, and wherein the outlets of the first inverter circuit and the second inverter circuit, respectively, of the voltage receiver represent outlet nodes.

11. The circuit arrangement of claim 10, wherein a third inverter circuit is connected between the first and second terminals, wherein an outlet of the third inverter circuit is connected with the inlet of the first inverter circuit of the voltage transmitter, wherein the inlet of the third inverter circuit is connected with the inlet of the second inverter circuit of the voltage transmitter, and wherein the inlet of the third inverter circuit is connected with a terminal IN as the inlet of the circuit arrangement for bridging high voltages with a switching signal.

12. The circuit arrangement of claim 10, wherein a fourth inverter circuit and a fifth inverter circuit are connected between the third and fourth terminals, wherein an inlet of the fourth inverter circuit is connected with the inlet of the first inverter circuit of the voltage receiver, wherein an inlet of the fifth inverter circuit is connected with the inlet of the second inverter circuit of the voltage receiver, wherein an outlet of the fourth inverter circuit is connected with a terminal OUT1 as the first outlet of the voltage receiver, and wherein an outlet of the fifth inverter circuit is connected with a terminal OUT2 as the second outlet of the voltage receiver.

13. The circuit arrangement of claim 10, wherein a sixth inverter circuit and a seventh inverter circuit are connected between the first and second terminals, wherein an inlet of the seventh inverter circuit is connected with the inlet of the third inverter circuit and with a terminal IN as the inlet of the circuit arrangement for bridging high voltages with a switching signal, wherein an outlet of the seventh inverter circuit is connected with an inlet of the sixth inverter circuit, and wherein an outlet of the sixth inverter circuit is connected with the inlet of the second inverter circuit of the voltage transmitter.

14. The circuit arrangement of claim 10, wherein an inverter circuit comprises two complementary transistors connected in series.

15. The circuit arrangement of claim 10, wherein the first capacitor and the second capacitor are connected between the voltage transmitter and the voltage receiver in such a way that the first capacitor and the second capacitor, respectively, are charged as high voltage capacitors to voltage differential to be overcome between the voltage transmitter and the voltage receiver and the charges of the first capacitor and second capacitor subsequently vary at a value ΔQ=C×(Vdd−Vss) for signal transmission, wherein power consumption of the circuit arrangement for bridging high voltages with a switching signal is independent from the voltage differential to be overcome between the voltage transmitter and the voltage receiver, and wherein simultaneously, the applied differential principle guarantees a high signal-to-noise ratio relative to push-push interference signals.

16. The circuit arrangement of claim 10, wherein the circuit arrangement for bridging high voltage with a switching signal is realized as an integrated semi-conductor circuit made with semi-conductor processes with CMOS circuits as the inverter circuits or a stack of layers with alternating layers of circuit stopper implantation, field oxide, poly-silicon, CVD-oxide, metal, CVD-oxide, metal, and so on, whereby the layers are electrically alternatingly connected, as the first capacitor and as the second capacitor, respectively, as high voltage capacitors.

17. The circuit arrangement of claim 10, wherein the voltage transmitter is one region or multiple regions of a semi-conductor chip, wherein the first capacitor is one region and the second capacitor is one region of the semi-conductor chip, wherein the voltage receiver is one region of the semi-conductor chip, wherein at least the region of the voltage transmitter and of the voltage receiver, respectively, is surrounded by a trench for voltage isolation.

18. The circuit arrangement of claim 10, wherein the circuit arrangement for bridging high voltages with a switching signal is realized as integrated semi-conductor circuits made with semi-conductor processes for integrated high voltage circuits with any isolation for the voltage transmitter, the high voltage capacitors, and the voltage receiver.
